(19) United States
(12) Patent Application Publication
(10) Pub. No.: US 2024/0420921 A1
(43) Pub. Date: Dec. 19, 2024

(54) IMMERSED PLASMA SOURCE AND PROCESS CHAMBER FOR LARGE AREA SUBSTRATES

(71) Applicant: APPLIED MATERIALS, INC., Santa Clara, CA (US)

(72) Inventors: Kenneth S. Collins, San Jose, CA (US); Tianhong Wang, Sunnyvale, CA (US); Kartik Ramaswamy, San Jose, CA (US); Craig Anton Rosslee, San Jose, CA (US); Oscar Lopez, San Jose, CA (US); Michael Rice, Pleasanton, CA (US)

(21) Appl. No.: 18/209,348

(22) Filed: Jun. 13, 2023

(51) Int. Cl. H01J 37/32

(52) U.S. Cl. CPC H01J 37/32119; H01J 37/32183; H01J 37/32449; H01J 37/32724; H01J 2237/002; H01J 2237/0262

(57) ABSTRACT

Embodiments disclosed herein include immersed inductively coupled and capacitively coupled plasma excitation methods, apparatuses and processes for large area substrates. A process chamber includes a pedestal for supporting a workpiece in a processing volume, an array of inductive elements in a portion of the processing volume above the pedestal, and a chamber top or lid over the array of inductive elements.

### FIELD

Embodiments of the present disclosure pertain to the field of semiconductor processing and, in particular, immersed inductively coupled and capacitively coupled plasma excitation methods, apparatuses and processes for large area substrates.

### DESCRIPTION OF RELATED ART

Traditional approaches for inductive coupling of power to plasma include the implementation of an externally located current-carrying inductive element (“coil”) placed adjacent to vacuum-atmosphere structural dielectric window. For large substrates this is problematic as suitable materials (e.g., ceramic) may be expensive or unavailable, the thickness must be greater, the distance coil-to-plasma greater, and magnetic mutual coupling reduced, with high losses. Scaling up these sources results in non-uniformities and high capacitive coupling.

### SUMMARY

Embodiments disclosed herein include a process chamber including a pedestal for supporting a workpiece in a processing volume. An array of inductive elements is in a portion of the processing volume above the pedestal. The array of inductive elements includes a plurality of parallel and planar inductive elements. A chamber top or lid is over the array of inductive elements.

Embodiments disclosed herein include a process chamber including a pedestal for supporting a workpiece in a processing volume. An array of inductive elements is in a portion of the processing volume above the pedestal. The array of inductive elements has a rectangular loop arrangement. A chamber top or lid is over the array of inductive elements.

Embodiments disclosed herein include an apparatus for including in a process chamber. The apparatus includes an array of inductive elements including a plurality of parallel and planar inductive elements, each one of the plurality of parallel and planar inductive elements including a conductive rod or tube surrounded by a dielectric tube.

### BRIEF DESCRIPTION OF THE DRAWINGS

FIG. 1A illustrates an angled view an array of rods/tubes for implementation in an upper region of a process chamber, in accordance with an embodiment of the present disclosure.

FIG. 1B illustrates an end-in view of the array of FIG. 1A, in accordance with an embodiment of the present disclosure.

FIG. 1C illustrates an end-in view of the array of FIG. 1A, in accordance with an embodiment of the present disclosure.

FIG. 2 illustrates a cross-sectional view of a process chamber including an array of rods/tubes in a portion of a processing volume, in accordance with an embodiment of the present disclosure.

FIG. 3A illustrates an angled view an array of rods/tubes for implementation in an upper region of a process chamber, in accordance with an embodiment of the present disclosure.

FIG. 3B illustrates an angled view another array of rods/tubes for implementation in an upper region of a process chamber, in accordance with an embodiment of the present disclosure.

FIGS. 4A and 4B illustrate angled views of portions of a process chamber including an array of rods/tubes in a processing volume, in accordance with an embodiment of the present disclosure.

FIGS. 5A and 5B illustrate top-down views of a portion of a process chamber including an array of rods/tubes in a processing volume, where a workpiece is rotated during processing, in accordance with an embodiment of the present disclosure.

FIG. 6A is a schematic showing a parallel immersed ICP rod/tube array, in accordance with an embodiment of the present disclosure.

FIG. 6B is another schematic showing a parallel immersed ICP rod/tube array, in accordance with another embodiment of the present disclosure.

FIG. 7 is a schematic showing a parallel immersed ICP rod/tube array, in accordance with an embodiment of the present disclosure.

FIG. 8 is a schematic showing a two parallel feed opposing RF magnetic field (alternating sides) arrangement, in accordance with an embodiment of the present disclosure.

FIG. 9 is a schematic showing a two parallel feed opposing RF magnetic field arrangement, in accordance with an embodiment of the present disclosure.

FIG. 10A is and angled view and FIG. 10B is a side view of a rectangular loop immersed inductively coupled plasma (ICP) rod/tube arrangement, in accordance with an embodiment of the present disclosure.

FIG. 11A is a diagram illustrating a top view of the plasma treatment chamber having a multiphase rotating crossflow operation according to one embodiment.

FIGS. 11B and 11C illustrate cross-section views of the plasma treatment chamber in different embodiments.

FIG. 12 illustrates a diagrammatic representation of a machine in the exemplary form of a computer system within which a set of instructions, for causing the machine to perform any one or more of the methodologies described herein, may be executed according to an embodiment.

### DETAILED DESCRIPTION

The disclosed embodiments relate to immersed inductively coupled and capacitively coupled plasma excitation methods, apparatuses and processes for large area substrates. In the following description, numerous specific details are set forth, in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

In accordance with one or more embodiments of the present disclosure, methods and apparatuses for exciting a uniform plasma with suitable characteristics for materials processing, e.g., etching, deposition or surface modification, for a large area substrate are described. Embodiments can employ a pumped vacuum chamber with an immersed array of dielectric insulated inductive power coupling elements, a current distribution recursive transmission line feed and return structure, a grounded chamber wall and an RF-biasable substrate support electrode and heat transfer interface.

Embodiments can be implemented to provide plasma excitation for large area substrate processing that overcomes practical problems: (1) RF dielectric window size limitations in suitable material for plasma processing, (2) plasma non-uniformities with large area substrates due to distributed circuit (standing wave) effects, voltage and current spatial variation along source, (3) minimizing capacitive coupling on unwanted surfaces (inductively coupled plasma (ICP) windows and ground electrodes), (3) maximizing capacitive coupling at substrate. Advantages for implementing embodiments described herein can include overcoming the above issues.

To provide context, state-of-the-art approaches have tried to scale up conventional flat or solenoidal coils (round or rectangular) on single large RF dielectric windows for large area substrate processing. Success has been limited by (1) availability and cost of large dielectric windows, which must also be thicker and size grows (to stand up to high atmospheric pressure/vacuum load). Thicker windows also force external coil elements to be farther from the plasma, which decreases power coupling efficiency. Scaling up conventional coils to large sizes can result in standing waves (current and voltage varying with position along a current carrying coil element) developed at electrical length (fraction of a wavelength in plasma at excitation frequency). This can produce poor power coupling uniformity and poor plasma and process uniformity. In addition, long electrical length is also associated with high voltage on coil elements, which leads to less suitable capacitive coupling from coil elements across dielectric window to plasma. This unwanted capacitive coupling is at the expense of sought after inductive coupling, and due to more energetic ion bombardment of dielectric window surface (and possibly nearby grounded chamber surfaces) leads to sputtering, etching and possible formation of contaminant films and particulate.

Other state-of-the-art approaches have attempted to use multiple conventional flat or solenoidal coils (round or rectangular) on single large RF dielectric windows or multiple RF dielectric windows mounted on a metal chamber frame. Uniformity has been a limiting factor on such designs.

Immersed rods in tubes within plasma for plasma sources have been implemented. State-of-the-art systems indicate that rod/tubes in arrays are arranged with connections in series, not paralleled as described in association with embodiments herein. In such state-of-the-art arrangements, ohmic connections are made between adjacent rod ends, such that the current path follows a ‘serpentine’ pattern, with currents in adjacent rods ‘out-of-phase’ approximately 180 degrees. The magnetic fields induced by the current flow on the surface of each rod oppose one another. These state-of-the-art systems typically operate at high frequency (i.e., 13.56 MHz) and rods are separated by at least several skin depths or many skin depths in the plasma under operating conditions, so once plasma is ‘on’ the induced fields do not destructively interfere with one another through the plasma. For rod/tube arrays sized for large area substrate processing, state-of-the-art approaches have identified several problems with such operation. The voltage and current on each rod/tune element are not constant, that is, at high frequency, standing waves develop and current and voltage both vary along an element. In addition, when the elements are series-connected, the voltages ‘add-up’ from element to element, produce a large and spatially varying voltage with respect to plasma and ground. The result is inductive power coupling varies with position along each element and element-to-element in the chamber. Additionally, capacitive coupling to plasma becomes significant and varies along each element and element to element. This not only affects process uniformity, but also results in sputtering or reactive ion etching of tube dielectrics, which may create a contamination and particle formation problem with for example ceramic tubes in fluorinated plasmas, or for example a consumable problem with quartz tubes. State-of-the-art approaches have tried to mitigate the non-uniformity problems by operating in a traveling wave mode, but this is a very complex solution. One might try to solve the capacitive coupling tube sputtering problem by utilizing Faraday (electrostatic) shields around rods inside tubes. This can be effective to suppress capacitive coupling, but normally comes at the expense of reduced efficiency due to high losses in shields. In addition, the probability of arcing between current carrying rods and adjacent electrostatic shield is high with a long rod at high frequency (high ‘electrical length’ of the line), unless a large gap there between is used.

Embodiments described herein can be implemented to overcome state-of-the-art problems with plasma sources including rods/tubes immersed in plasma and series-connected by reducing source frequency to reduce voltage and current variation (lower ‘electrical length’ of the line) along the line and to reduce rod voltage. The issue discovered was that the rod/tubes had to be more widely separated in the array to avoid destructive interference in plasma, as the interference greatly increased power losses (reduced power coupling efficiency) since rod currents at lower frequency must be much higher to deliver the same power under out-of-phase or opposing conditions. Another issue with separating the rods further within the array is that the distance from the rod array to the substrate must be increased to avoid ‘stripes’ or ‘ripple’ pattern in the plasma uniformity due to weaker plasma between rods. Increasing the distance significantly from the rod array to the substrate increases the recombination of species generated near power deposition regions near rods/tubes and transported to substrate, changing the local chemistry at substrate.

In an embodiment, a substrate support pedestal resides in a vacuum chamber with a top surface generally facing and generally parallel to vacuum chamber inside top ceiling surface. The chamber walls are typically grounded and may be bare metal (typically aluminum), anodized, coated, or employ wall liners. The pedestal typically includes an electrostatic chuck (‘esc’), monopolar or multipolar, for clamping a substrate (semiconductor, dielectric or conductor) to a surface to facilitate heat transfer (temperature control) and power coupling (biasing), and to maintain flatness and parallelism of a substrate to said surface. A heat transfer fluid may be exchanged between pedestal or electrostatic chuck (ESC) and an external heat exchanger or chiller. A heat transfer gas may be supplied to the interface between esc surface and backside of substrate to facilitate heat transfer there between. The pedestal or ESC may include electrical resistance heaters within its structure, with filtering isolation. An RF bias generator may be connected via a matching network and optional transmission line to pedestal or ESC. An electrostatic chuck voltage source may be connected to the ESC to establish and maintain an electrostatic clamping force (pressure) between substrate and ESC. RF bias and electrostatic chucking voltage may be connected to common electrode with the ESC, or may be connected to separate electrodes within the ESC. Alternatively, ESC chucking voltage may be connected to a chucking electrode within the ESC, and RF bias may be connected to pedestal conductive electrode. In any of all of these cases, filters may be employed to properly isolate said power or voltage or current source from one another, and to isolate heater elements from external ac or dc power supply. In one embodiment, the pedestal is at a fixed position relative to chamber. In another embodiment, the pedestal has z-axis motion to facilitate substrate transfer to/from transfer chamber and robot blade. In another embodiment, the pedestal has an adjustable height, providing a process-recipe or process-operation selectable gap between substrate pedestal and rod/tube array to maximize process uniformity. In yet another embodiment, the pedestal may rotate or oscillate in x-y plane to maximize process uniformity.

In accordance with an embodiment of the present disclosure, an upper region of a process chamber includes a generally parallel and generally planar array of two or more conductive rods or tubes, herein called ‘inductive elements “, surrounded by dielectric tubes which function as RF windows, with a vacuum, air, gas or liquid gap between inductive element and inside of dielectric tube. This array of rods and tubes penetrates through mutually opposite walls of the generally rectangular vacuum chamber, sealing on the tubes at each end. The rods (inductive elements) are ‘fed’ RF current from a matching network via a recursive transmission line current-splitting structure from one side, and, optionally, on the opposite side the rods have current returned to the matching network or ground through a similar recursive transmission line current-combining structure. Capacitor(s) may be used in series or parallel with individual elements or entire array, to create a virtual ground region or to adjust impedance. In an embodiment, generally planar and generally parallel can encompass a range of non-planarity and a range of non-parallelism, e.g., +/−15 degree non-parallel or non-planar, or two planes that are substantially parallel but not co-planar.

In an embodiment, the (conductive) pedestal and ESC may extend beyond the size of the substrate to maximize uniformity of sheath (boundary layer in plasma) electric field over the substrate. The pedestal and ESC may be surrounded along the edge(s) with dielectric, and a grounded metal (uncoated or coated) may surround the dielectric. A process kit, dielectric or semiconductor, may cover the exposed portion of the ESC outside the substrate, and may extend over the surrounding dielectric region.

In an embodiment, gas can be introduced through one or more inlets or nozzles in the chamber ceiling or one or more chamber sides, and may evacuated with a pump (or turbomolecular pump) in a central region below the pedestal or other asymmetric region in the chamber bottom or one or more sides. With a non-central/symmetric pump port location, it may be advantageous to use a gas manifold or flow baffle to facilitate uniform pumping and pressure distribution. Multiple pump ports/pumps may be employed at, for example, 4 bottom corners, for a 4-fold symmetric pumping arrangement. A throttle valve and gate valve, or a throttling gate valve would typically be employed in conjunction with a pressure gauge (e.g., capacitance manometer) for chamber pressure control.

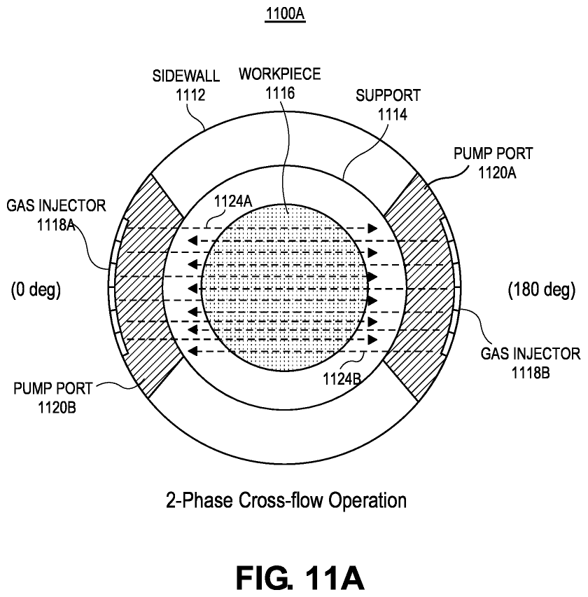

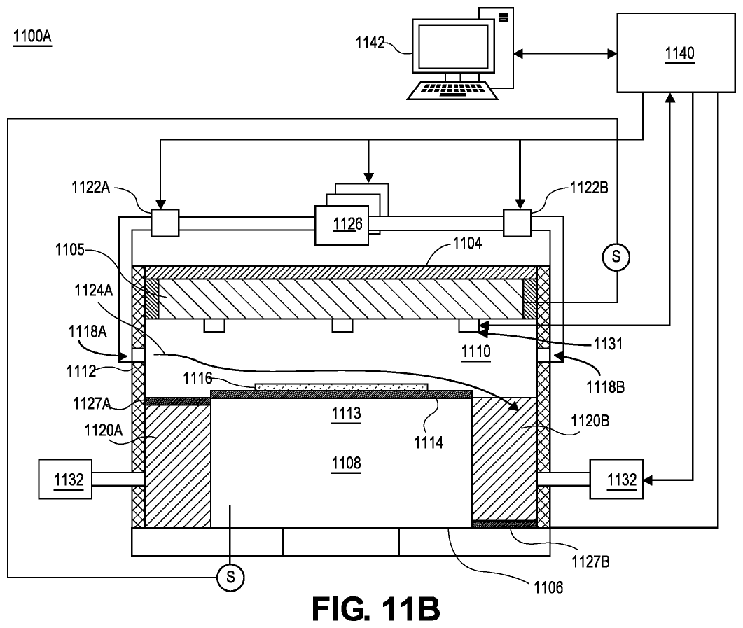

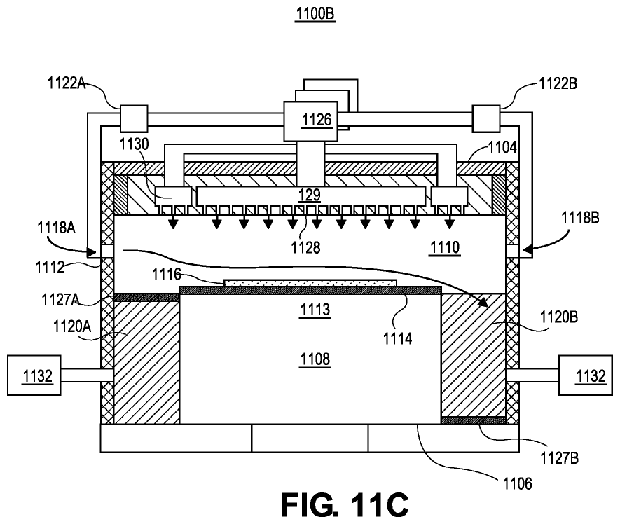

An alternative embodiment utilizes ‘cross-flow’, with gas inlets located generally near one wall or side region of chamber (on wall, ceiling, or bottom) and pumping generally located on/near opposite side/wall/bottom of chamber, examples of which are described below in association with FIGS. 11A-11C. This arrangement facilitates higher horizontal gas velocity and lower gas residence time across the substrate, which can be suitable for some processes. A second inlet and opposite outlet can be located 180 degrees rotated with respect to the first set or each, and sequential or phase 2-phase operation can alternate flow direction. Finally, inlets and outlets can be placed on/near each side, with inlets 90 degrees apart, and respective outlets opposite said inlets, and 4-phase operation can operate sequentially or with phased operation to rotate flow for best uniformity. Alternatively, a single inlet on 1 side and outlet on opposite side can be combined with a rotating substrate pedestal for best uniformity.

In an embodiment, an RF source power is coupled via the source matching network to the plasma source feed structure and return structure. The rods (inductive elements) are ‘fed’ RF current from a matching network via a recursive transmission line current-splitting structure from one side and are grounded at or near the opposite side of chamber, or optionally, on the opposite side the rods have current returned to the matching network or ground through a similar recursive transmission line current-combining structure. Capacitor(s) may be used in series or parallel with individual elements or entire array, to create a virtual ground region or to adjust impedance or approximately resonate structure.

In an embodiment, for large substrates, generally the chamber size is selected to be larger than the substrate by a substantial margin. For a 0.5×0.5 meter substrate, an inside chamber size may be selected to be 0.6×0.6 m or 0.7×0.7 meter in x and y dimensions. It may be suitable to select chamber size to be even larger, e.g., 0.8×0.8 meter, or most suitable larger yet, i.e. 0.9×0.9 meter. The chamber does not need to be square, but for parallel feed of currents, in an embodiment the rod/tubes should have mutually equal length and approximately equal self-inductances under operating conditions in plasma. It is to be appreciated that with no plasma, end rods will have greater different inductances than interior rods due to proximity of adjacent rods and walls. It is also to be appreciated that the size of the peripheral region around the pedestal housing relative to the size of the chamber defines the maximum area available for pumping (conductance), so should also be considered when selecting chamber size.

In an embodiment, the plane of the rod/tube array is located generally parallel to the chamber ceiling and to the substrate support pedestal. The optimum height of the chamber is determined by both the gap between the rod/tube array to substrate and the gap between rod/tube array and the chamber ceiling.

In an embodiment, in a parallel feed arrangement, the currents of adjacent rods are fed ‘in-phase’, with constructive interference. In this parallel feed arrangement, in-phase magnetic fields produce the highest coupling efficiency (lowest losses), because rods operate at the lowest current per rod. By operating at reduced frequency (compared to 13.56 MHz), the voltage and current variation along each rod is reduced (very small standing wave effects), and the total voltage developed on each rod is for a given power is reduced. By driving the rods in parallel, there is no voltage ‘stack-up’ along the array of rods. This selection of parallel current feed at lower frequency can result in improved power coupling and resultant plasma uniformity, and can maximize inductive coupling efficiency while minimizing capacitive coupling from array. It may present one problem, however, how to feed array and ensure minimal variation in current in each rod within array. In an embodiment, a potential improvement over simply having a bus connecting all rod ends on one side of array together, and a second bus connecting all rod ends of opposite side of array together, and feed first side from RF match and grounding second opposite side is the following: the rods are ‘fed’ RF current from a matching network via a recursive transmission line current-splitting structure from one side and grounded at or near the opposite side, or optionally, on the opposite side the rods have current returned to the matching network or ground through a similar recursive transmission line current-combining structure. Capacitor(s) may be used in series or parallel with individual elements or entire array, to create a virtual ground region or to adjust impedance or approximately resonate structure. In an embodiment, a series capacitor(s) placed in each rod current path or in the total current path may be adjusted to produce a virtual ground (V=0) point, line or region at a location in the chamber around the array; this may be useful to maximize symmetry of plasma uniformity. In an embodiment, a capacitor(s) may be place in parallel with one or both ends of each rod or the array of rods, or at the RF match output and return, to allow adjustment of the plasma-loaded rod array impedance. Depending on the plasma conditions and resulting load, it may be suitable to approximately resonate the plasma-loaded rod array at the drive frequency. This may reduce current demand from RF match and losses in RF delivery system, resulting in higher power coupling efficiency to plasma.

In an embodiment, with a parallel current feed arrangement, rods fed on one side and grounded (directly or indirectly) on the opposite side, the primary return current within the chamber is carried of the inside surface of the chamber surfaces.

In an embodiment, to further minimize capacitive coupling between rods and plasma (to minimize sputtering or etching of tubes and contamination/particle formations or to reduce consumption of tubes), it was found that a greater gap between rod radius and inside tube radius can be selected, using a thin wall tube or increasing tube radius. In one embodiment, with 8 rod/tube elements 100 mm apart on center in a 0.85×0.85 m chamber, with RF source frequency=2 MHz, 6.25 mm copper rods and used within 12.5 mm outside radius dielectric tubes, with 5 mm wall thickness. In a specific embodiment, wall thickness is reduced to 4 mm. In an even more specific embodiment, tube outside radius is increased to 18.25 mm and tube wall is 3 mm. Dielectric constant of tube can also affect capacitive coupling from rod to plasma. Quartz with epsilon relative of 4.2 provides lower capacitive coupling than for example aluminum oxide with epsilon relative of 9, however quartz etches with volatile by-products in fluorinated etch chemistry while aluminum oxide has a non-volatile by-product, aluminum fluoride, which can be problematic and form particles.

In an embodiment, an important factor in minimizing reaction rate of tubes in reactive plasmas (such as etching or cleaning plasmas containing fluorinated, other halogen, or hydrogen containing species) is surface temperature. In one embodiment the copper rods are actually tubes, composed of stainless steel and plated with copper (and optionally silver, on top of copper, to at least several skin depths in the metal top layers at the driven frequency, and flowing liquid is used to convectively cool the tube. In another embodiment, not only is the rod liquid cooled, but additionally the inside surface of the tube is air cooled by forced convection. In a specific embodiment, dielectric liquid is used for forced convection of the inside tube wall, using a recirculating heat exchanger with temperature controlled fluid.

In an embodiment, the most suitable distance from rod/tube array to substrate can depend on several factors, including spacing between rods/tubes, plasma composition (chemistry, pressure). As mentioned above, for large spacing rod/tube array to substrate, significant recombination of reactive species can occur from where species are generated near power deposition regions near rods/tubes and transported to substrate, changing the local chemistry at substrate. If spacing array-to-substrate is too small relative to spacing between rods/tubes, then a ‘stripes’ or ‘ripple’ pattern in the plasma uniformity due to weaker plasma between rods may be present near the substrate. In one embodiment, with 8 rod/tube elements 100 mm apart on center in a 0.85×0.85 m chamber, the centerline distance of rod/tube array to substrate is selected to be 150 mm. Suitability can vary with process application and plasma conditions. In some applications, it may be useful to have a pedestal with variable height capability, to control the distance between rod/tube array and substrate per recipe or process operation.

In accordance an embodiment of the present disclosure, the effect of distance from rod/tube array to chamber inside top ceiling has been investigated by plasma modeling. This distance and the resulting chamber area and volume affect the power coupling of the rod/tube array to the plasma, and the overall spatial dependence of the plasma species densities and fluxes. In addition, bias power applied to cathode (substrate support pedestal) requires a return path distributed around chamber ground surfaces, and this is affected by plasma density distribution. With a smaller gap from rod/tube array to chamber inside top ceiling as compared to gap from rod/tube array to chamber bottom (or substrate pedestal electrode), modeling investigation has found that lower plasma species density (i.e., electron and ion number densities) result in the upper, smaller gap region, Vs the larger lower gap region. This may have a disadvantageous impact of the effective utilization of the upper chamber wall surfaces on the RF bias ground return path. It was found when the top gap and bottom gap were similar, or at least when the top gap was large enough, that power coupling from rod array to top and bottom regions became more top/bottom symmetric, resulting in similar top/bottom region plasma number densities, and more effective participation of upper chamber wall region in RF ground path. This may be suitable to maximize bias power utilization as ion energy flux (power) at the smaller substrate pedestal electrode surface versus at the larger chamber ground electrode.

In one embodiment, with 8 rod/tube elements 100 mm apart on center in a 0.85×0.85 m chamber, the centerline distance of rod/tube array to substrate 150 mm, the centerline distance of the rod/tube array to chamber ceiling was varied between 50 mm and 150 mm. Under select etch conditions (5 kW source power at 2 MHz, 250V at 13.56 MHz bias power, 20 mTorr pressure, 60% Argon,30% CF4,10% O2), it was found that the greater (150 mm) and symmetric distance above and below the rod/tube plane to top/bottom chamber surfaces (chamber ceiling at top, substrate pedestal at bottom) provided a better RF bias ground path, with lower ion energy flux (ion power) to grounded chamber surfaces and higher ion energy flux to substrate, with similar ion currents and radical fluxes to substrate as the 50 mm top spacing case. The non-uniformity of important species-dependent ion currents and radical species to substrate was ‘good’ in both cases, though slightly worse with the taller gap between rod/tube array and chamber ceiling.

In an alternative embodiment, the array of inductive elements are connected in-phase by connecting the ‘far’ end of a 1^{st} rod back to the opposite or ‘near’ end of the adjacent rod, normally through a shielded transmission line enclosure outside the vacuum chamber. This produces in-phase or aiding magnetic fields, but uses a series wiring arrangement.

As such, a useful constructive interference results, but the voltages ‘stack-up’ through the array, so a high additive voltage results, for an 8 rod array, the voltage developed across the array is about 8× that of an individual element which may not be suitable from a capacitive coupling perspective. Nevertheless, at sufficiently low frequency (inductance reactance of rod is proportional to frequency) this may be a viable configuration that may be most useful under certain conditions. Advantages can include (1) the same current is used to feed all inductive elements (rods) with no special distribution apparatus required, and the total current required for an 8 rod array is about ⅛× that of the parallel current feed method (this puts less demand on the RF match and power delivery system, so lower losses may result—and if the frequency is low (i.e., 400 kHz) then standing waves are insignificant over typical dimensions of less than 1 m×1 m, and voltage may be acceptable low, resulting in high inductive power coupling efficiency and acceptable inductive power coupling uniformity, and acceptable (minimal) capacitive coupling.

Optionally, in an embodiment, a Faraday shield can used inside tube inner radius, and with the low frequency and resultant low ‘electrical length’ of the rod, the voltage is lower and arcing risk can be minimal. Capacitor(s) may be used in series or parallel with the series-wired array, to create a virtual ground region or to adjust impedance or approximately resonate structure. In an embodiment, a series capacitor(s) placed in the total current path may be adjusted to produce a virtual ground (V=0) point, line or region at a location in the chamber around the array; this may be useful to maximize symmetry of plasma uniformity. In an embodiment, a capacitor(s) may be place in parallel with one or both ends of the series-wired array of rods, or at the RF match output and return, to allow adjustment of the plasma-loaded rod array impedance. Depending on the plasma conditions and resulting load, it may be useful to approximately resonate the plasma-loaded rod array at the drive frequency. This may reduce current demand from RF match and losses in RF delivery system, resulting in higher power coupling efficiency to plasma.

In an embodiment, with a Faraday shield in any design described, a double-walled tube may be used to provide better arc preventing that just an air or gas gap between rod and Faraday shield. Cooling air, gas or fluid may be force convected between walls of outer/inner tube in such a case.

In an embodiment, a plasma source and chamber described herein can be implemented to provide an improvement over state-of-the-art methods, apparatus and processes for low pressure plasma etching, cleaning, deposition or surface modification over large substrate, e.g., greater than 300 mm diameter wafers, and particularly useful for large semiconductor, dielectric substrates, whether glass, glass filled epoxy or other organic materials, with or without semiconductor or conductor (metal) materials, as may be used for packaging.

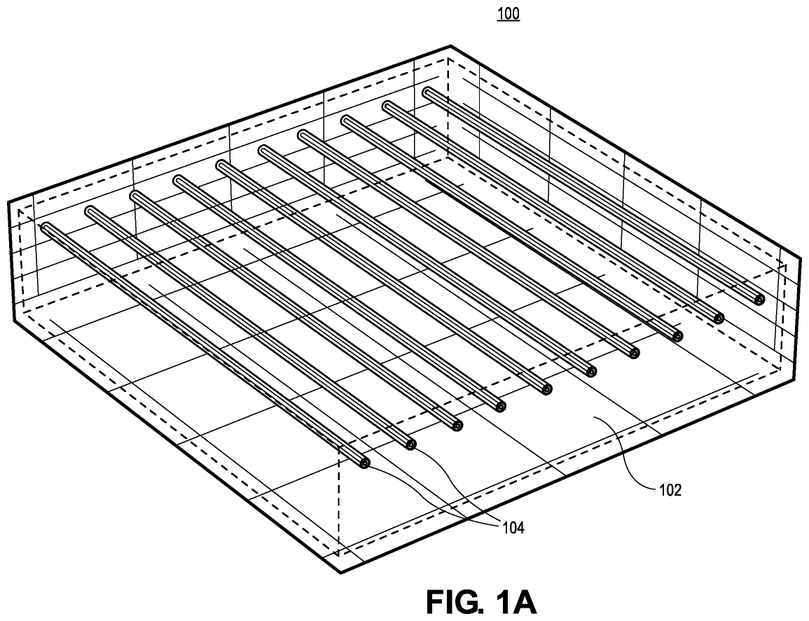

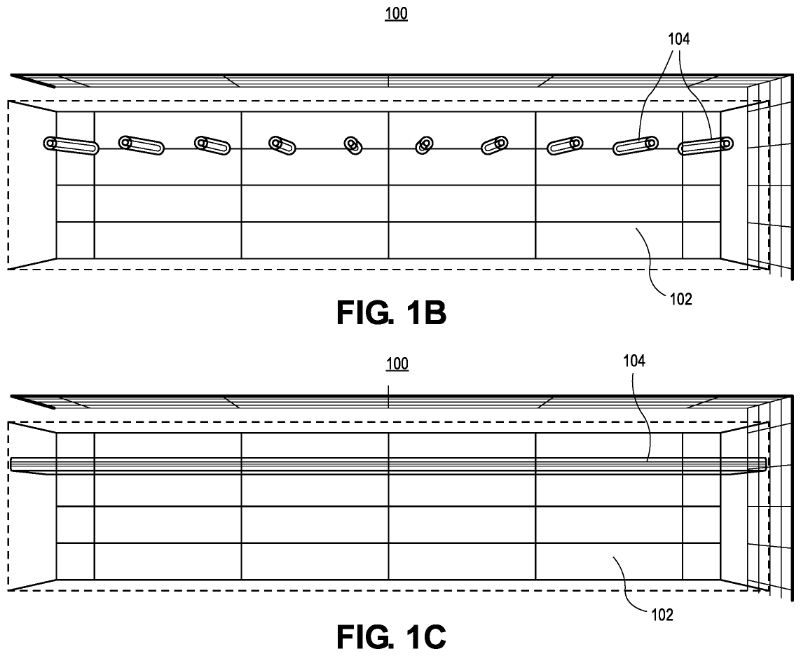

As an exemplary array of rods/tubes, FIG. 1A illustrates an angled view an array of rods/tubes for implementation in an upper region of a process chamber, in accordance with an embodiment of the present disclosure. FIG. 1B illustrates an end-in view of the array of FIG. 1A, in accordance with an embodiment of the present disclosure. FIG. 1C illustrates an end-in view of the array of FIG. 1A, in accordance with an embodiment of the present disclosure.

Referring to FIGS. 1A, 1B and 1C, an array 100 of rods/tubes includes a plurality of rods/tubes 104 in a portion 102 of a chamber volume, e.g., a portion of a chamber volume above a workpiece for processing. In one embodiment, 10 rods/tubes 104 are depicted. It is to be appreciated that other numbers of rods/tubes 104 may be used (e.g., less than or greater than 10). In an embodiment, the plurality of rods/tubes 104 is a plurality of substantially parallel rods/tubes 104 and substantially planar rods/tubes 104, as is depicted.

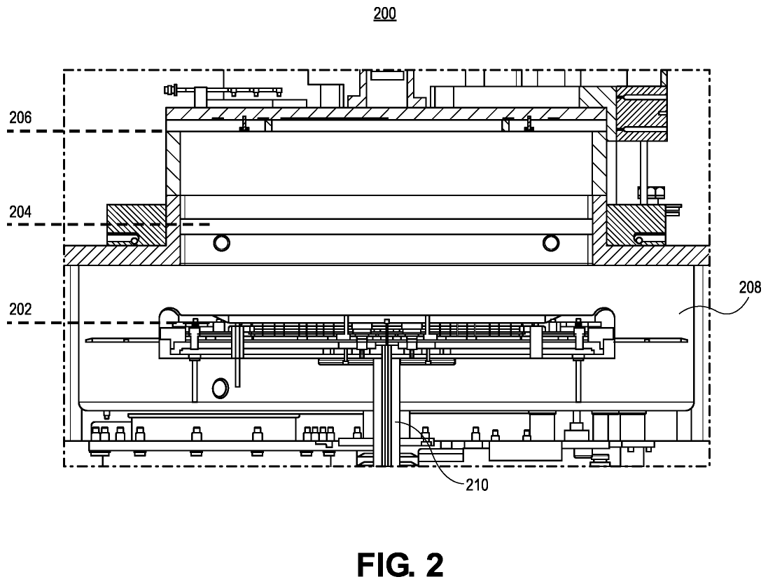

As an exemplary process chamber, FIG. 2 illustrates a cross-sectional view of a process chamber including an array of rods/tubes in a portion of a processing volume, in accordance with an embodiment of the present disclosure.

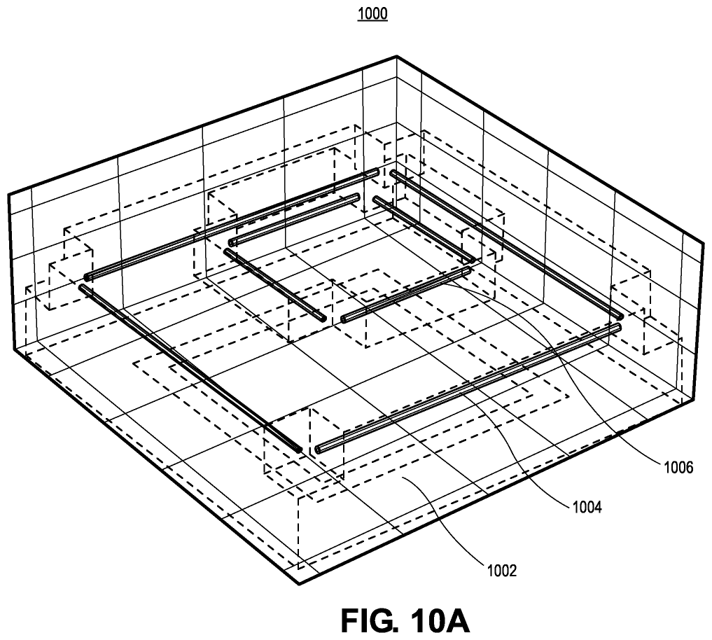

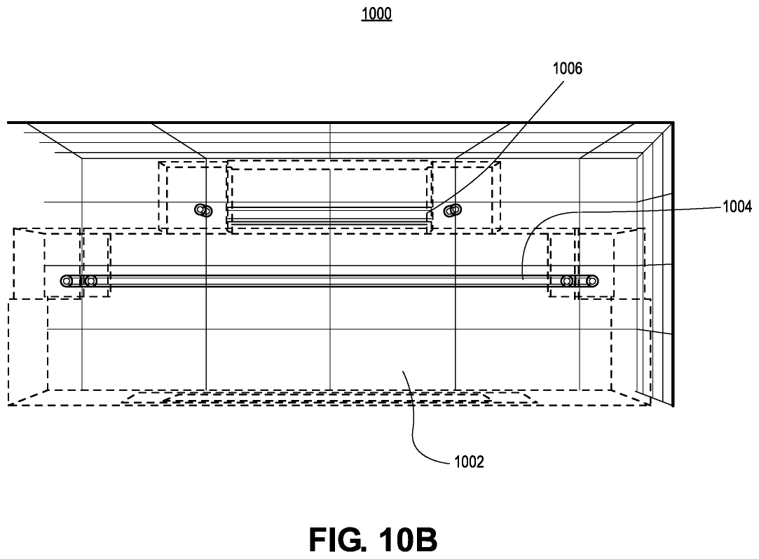

Referring to FIG. 2, a process chamber 200 includes a pedestal 202, e.g., for supporting a workpiece, in a processing volume 208. In one embodiment, the pedestal 202 is an electrostatic chuck. An array of rods/tubes 204 is included in a portion of the processing volume above the pedestal 202. A chamber top or lid 206 is over the array of rods/tubes 204. A shaft 210 can be coupled to the pedestal 202. In an embodiment, the array of rods/tubes 204 is a parallel and planar array, such as described above in association with FIGS. 1A, 1B and 1C. In another embodiment, the array of rods/tubes 204 is a rectangular loop array, such as described below in association with FIGS. 10A and 10B.

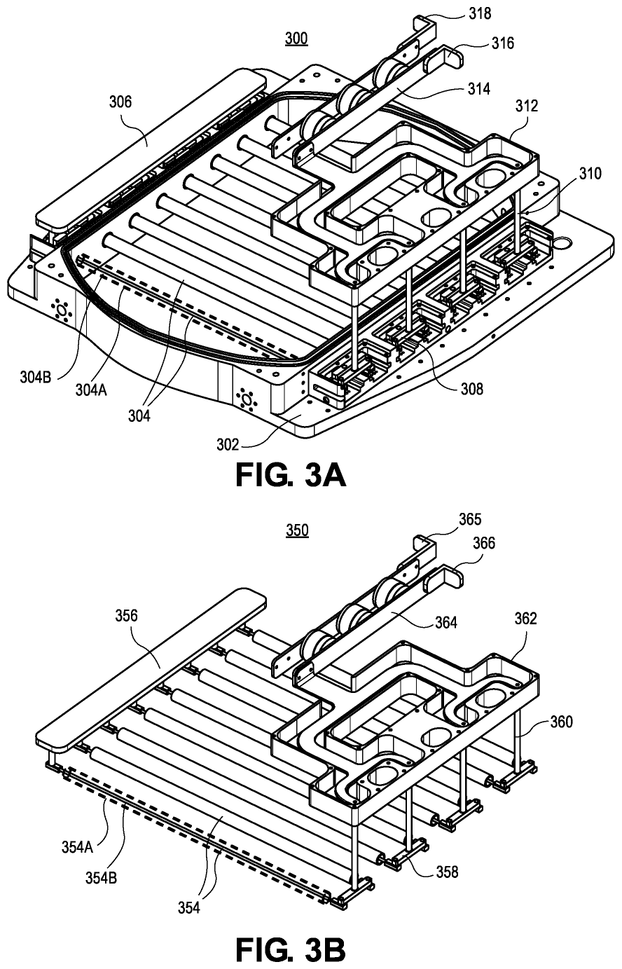

As an exemplary array of rods/tubes, FIG. 3A illustrates an angled view an array of rods/tubes for implementation in an upper region of a process chamber, in accordance with an embodiment of the present disclosure.

Referring to FIG. 3A, an array 300 of rods/tubes for implementation in an upper region of a process chamber includes a frame 302, and a plurality of substantially parallel and planar rods/tubes 304 within the frame 302 (with the closest rod/tube showing a dielectric tube 304A surrounding an inductively coupled plasma rod 304B exemplary for each rod/tube 304). A ground bus 306 is for bolting to a side of a chamber with continuous contact through an RF gasket (optional capacitor(s) in series between end of ICP rod and ground not shown). A recursive transmission line 308 is included for final current split. A recursive transmission line feed structure 310 (lower portion) is included, where an individual ground tube around each vertical via has been removed from view for clarity. A recursive transmission line feed structure 312 (upper section) is coupled to the recursive transmission line feed structure 310 (lower portion). A capacitor bank 314 is coupled to the recursive transmission line feed structure 312 (upper section). An RF match output 316 is coupled to the capacitor bank 314. A grounded to RF match input 318 is also coupled to the capacitor bank 314.

As another exemplary array of rods/tubes, FIG. 3B illustrates an angled view an array of rods/tubes for implementation in an upper region of a process chamber, in accordance with an embodiment of the present disclosure.

Referring to FIG. 3B, an array 350 of rods/tubes for implementation in an upper region of a process chamber includes a plurality of substantially parallel and planar rods/tubes 354 (with the closest rod/tube showing a dielectric tube 354A surrounding an inductively coupled plasma rod 354B exemplary for each rod/tube 354). A ground bus 356 is for bolting to a side of a chamber with continuous contact through an RF gasket (optional capacitor(s) in series between end of ICP rod and ground not shown). A recursive transmission line 358 is included for final current split. A recursive transmission line feed structure 360 (lower portion) is included, where an individual ground tube around each vertical via has been removed from view for clarity. A recursive transmission line feed structure 362 (upper section) is coupled to the recursive transmission line feed structure 360 (lower portion). A capacitor bank 364 is coupled to the recursive transmission line feed structure 362 (upper section). An RF match output 366 is coupled to the capacitor bank 364. A grounded to RF match input 368 is also coupled to the capacitor bank 364.

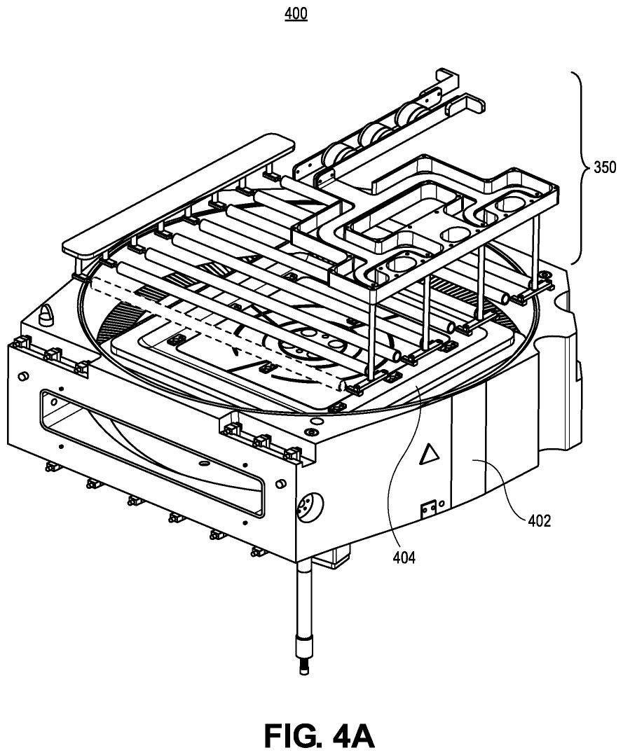

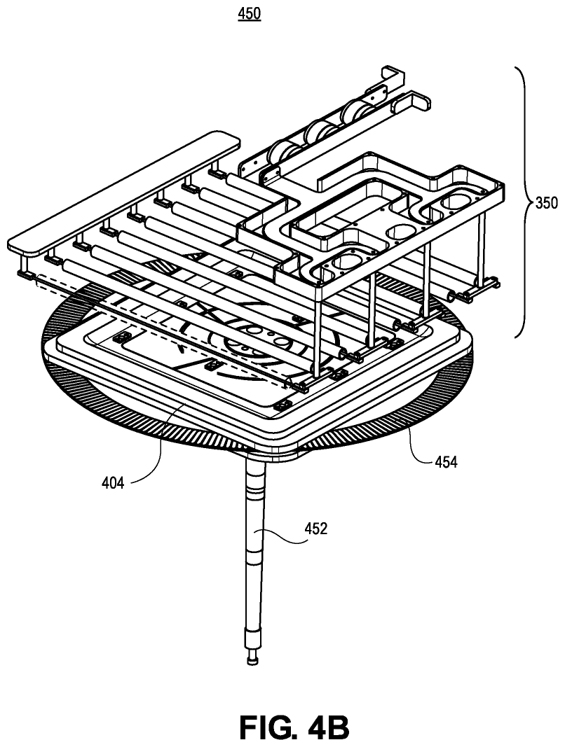

As an exemplary process chamber, FIGS. 4A and 4B illustrate angled views of portions of a process chamber including an array of rods/tubes in a processing volume, in accordance with an embodiment of the present disclosure.

Referring to FIG. 4A, a portion 400 of a process chamber includes a supported workpiece 404 surrounded by a chamber wall 402. An array of rods/tubes 350 (e.g., the array from FIG. 3B) is included in a portion of the processing volume above the supported workpiece 404. Referring to FIG. 4B, a portion 450 of the process chamber includes a pedestal 454 for supporting the workpiece 404 in a processing volume. In one embodiment, the pedestal 454 is an electrostatic chuck. An array of rods/tubes 350 (e.g., the array from FIG. 3B) is included in a portion of the processing volume above the pedestal 454. A shaft 452 can be coupled to the pedestal 454. In an embodiment, the array of rods/tubes 350 is a parallel and planar array, such as described above in association with FIG. 1A, 1B, 1C, 3A or 3B. In another embodiment, the array of rods/tubes is a rectangular loop array, such as described below in association with FIGS. 10A and 10B.

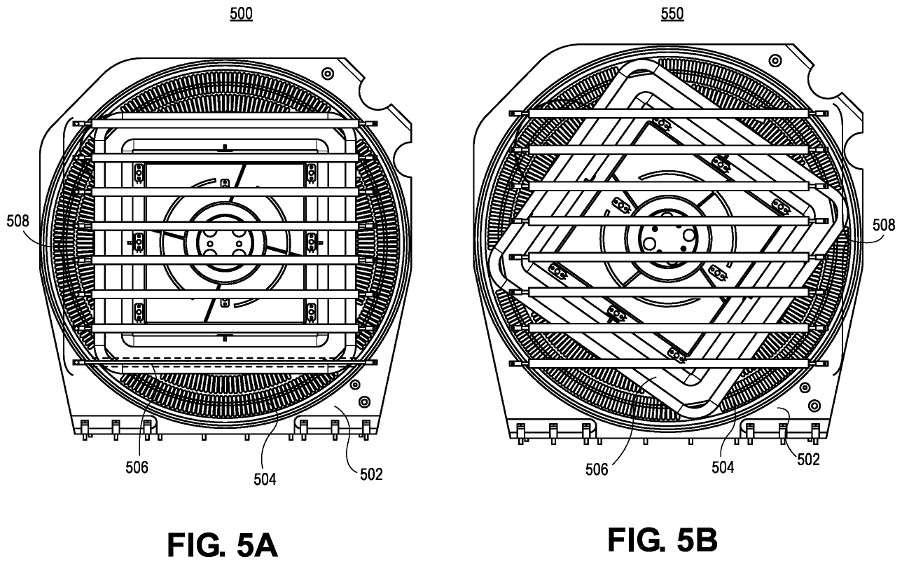

It is to be appreciated that in some embodiments, the workpiece 404 is processes in a fixed position. In other embodiments, the workpiece 404 is rotated during processing. As an exemplary process, FIGS. 5A and 5B illustrate top-down views of a portion of a process chamber including an array of rods/tubes in a processing volume, where a workpiece is rotated during processing, in accordance with an embodiment of the present disclosure.

Referring to FIG. 5A, in a first position 500, a workpiece 506 is supported by a pedestal 504 surrounded by a chamber wall 502. An array of rods/tubes 508 is included in a portion of the processing volume above the pedestal 504. In an embodiment, the array of rods/tubes 508 is a parallel and planar array, such as described above in association with FIG. 1A, 1B, 1C, 3A or 3B. In another embodiment, the array of rods/tubes is a rectangular loop array, such as described below in association with FIGS. 10A and 10B. The array of rods/tubes 508 is aligned with the workpiece at this first position 500.

Referring to FIG. 5B, the workpiece 506 is rotated during processing, with a second position 550 shown. The array of rods/tubes 508 is not aligned with the workpiece at this second position 550.

As described above, in an embodiment, a parallel immersed ICP rod/tube array is implemented. In one embodiment, the parallel immersed ICP rod/tube array is implemented for aiding RF magnetic fields.

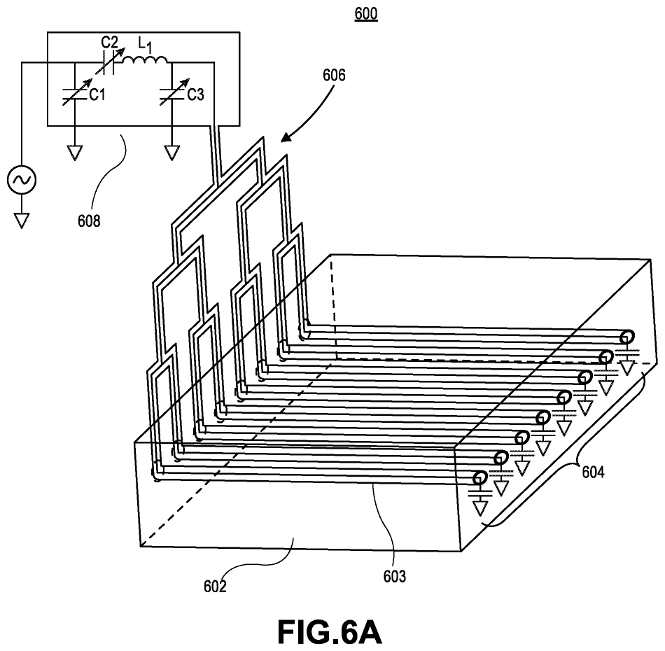

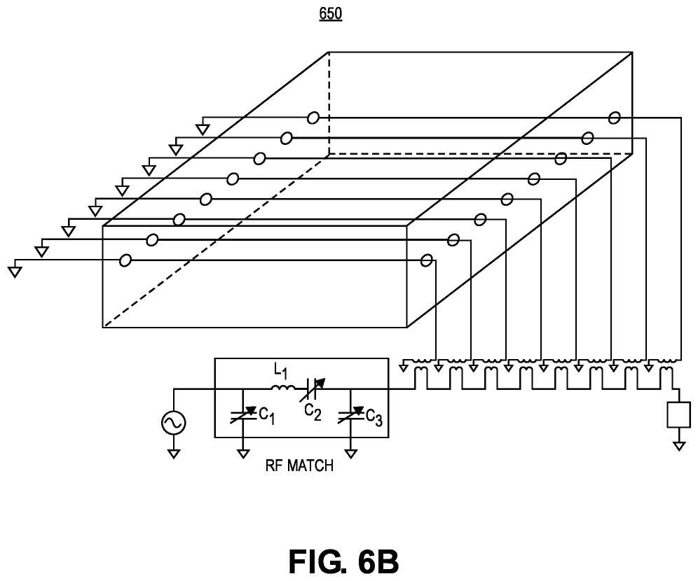

An ICP rod/tube array can be electrically driven in parallel from one side. As an example, FIG. 6A is a schematic 600 showing a parallel immersed ICP rod/tube array, in accordance with an embodiment of the present disclosure. Referring to FIG. 6A, a chamber volume 602 has an ICP rod/tube array 603 therein. A grounded end 604 has termination impedances such as capacitors (variable or fixed) on a per rod basis or collectively. An RF source is coupled to an RF matching network 608 which is coupled to a recursive transmission line feed structure 606 coupled to the rods 603. The RF matching network 608 can include parallel element in the match, or an external element such as a capacitor bank can be included.

As another example, FIG. 6B is another schematic 650 showing a parallel immersed ICP rod/tube array, in accordance with another embodiment of the present disclosure. Referring to FIG. 6B, in contrast to FIG. 6A, external transformers are included with series-connected primaries and parallel-connected secondaries.

Referring to FIGS. 6A and 6B, in accordance with one or more embodiments of the present disclosure, aiding RF magnetic fields electrically driven in parallel from one side can be (1) driven through a current splitter feed structure, where a current splitter feed structure is a recursive transmission line, (2) other side grounded through ohmic connection to chamber (locally), (3) other side grounded through impedance element (locally), where impedance element is a capacitor or inductor (fixed or variable), or where impedance element is an LC circuit (fixed or variable), or (4) other side grounded through a current combiner return structure, where current combiner return structure is a recursive transmission line, where current combiner return structure is grounded through ohmic connection, or where a current combiner return structure is grounded through impedance element (where impedance element is a capacitor or inductor (fixed or variable), or where impedance element is an LC circuit (fixed or variable).

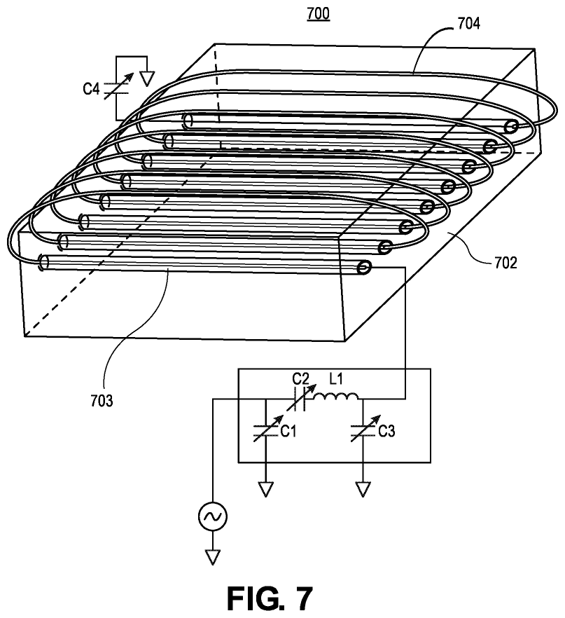

In another embodiment, a parallel immersed ICP rod/tube array is implemented for aiding RF magnetic fields, and can be electrically driven in series. As an example, FIG. 7 is a schematic 700 showing a parallel immersed ICP rod/tube array, in accordance with an embodiment of the present disclosure. Referring to FIG. 7, a chamber volume 702 has a rod/tube array 703 therein. A series feed in phase arrangement includes transmission line connections 704.

Referring to FIG. 7, in accordance with one or more embodiments of the present disclosure, aiding RF magnetic fields electrically driven in series can be driven at a first end of a first rod, with a second end of first rod electrically connected to the first end of the second rod, with the second end of second rod electrically connected to the first end of a third rod, etc., with a second end of a last rod grounded, (1) where the second end of the last rod is grounded through ohmic connection to the chamber (locally), where the second end of the last rod is grounded through impedance element connected to chamber (locally), and where (a) the impedance element is a capacitor or inductor (fixed or variable), or (b) where impedance element is an LC circuit (fixed or variable), or (2) where connections between rod ends are made through transmission line structures.

As described above, in an embodiment, a parallel immersed ICP rod/tube array is implemented. In one embodiment, the parallel immersed ICP rod/tube array is implemented for opposing RF magnetic fields.

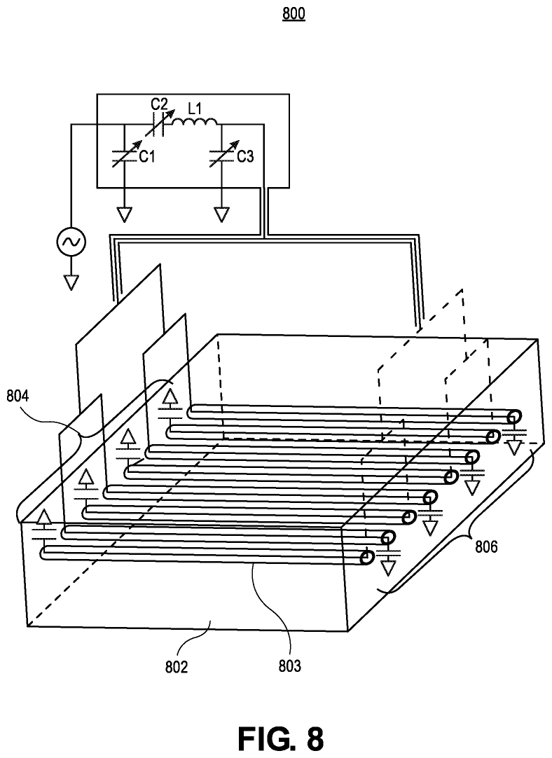

An ICP rod/tube array can be electrically driven in parallel from two sides. As an example, FIG. 8 is a schematic 800 showing a two parallel feed opposing RF magnetic field (alternating sides) arrangement, in accordance with an embodiment of the present disclosure. Referring to FIG. 8, a chamber volume 802 has an ICP rod/tube array 803 therein. Termination capacitors 804 are on one end, and termination capacitors 806 are on a second end.

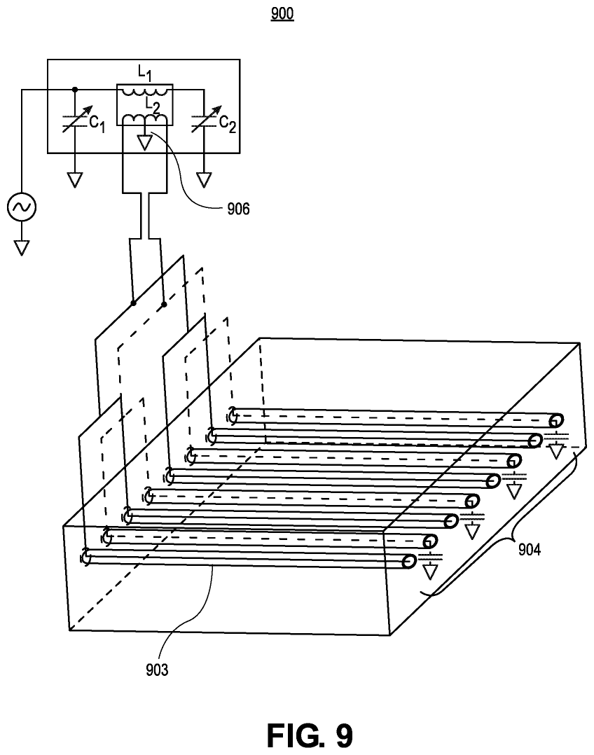

An ICP rod/tube array can be electrically driven from one side. As an example, FIG. 9 is a schematic 900 showing a two parallel feed opposing RF magnetic field arrangement, in accordance with an embodiment of the present disclosure. Referring to FIG. 9, a chamber volume 902 has an ICP rod/tube array 903 therein. Grounded ends of coil rods are achieved through termination capacitors 904, which are optional. In one embodiment, a center tapped transformer 906 is included.

In accordance with other embodiments of the present disclosure, a rectangular loop immersed inductively coupled plasma (ICP) rod/tube arrangement is included in a processing volume above a workpiece.

As an exemplary arrangement, FIG. 10A is and angled view and FIG. 10B is a side view of a rectangular loop immersed inductively coupled plasma (ICP) rod/tube arrangement 1000, in accordance with an embodiment of the present disclosure.

Referring to FIGS. 10A and 10B, a chamber volume 1002 has a first rectangular rod/tube array 1004 therein. A second rectangular rod/tube array 1006 is above the first rectangular rod/tube array 1004. In one embodiment, the second rectangular rod/tube array 1006 is with the first rectangular rod/tube array 1004 from a top-down perspective, as is depicted.

With reference to arrangements exemplified in FIGS. 10A and 10B, in an embodiment, for each substantially square coil, the coil segments can be connected in series, with one single corner of each set having an input from RF match, and next to it a ground point, through an optional capacitor. Alternatively, the coil segments can each have 1 of 4 parallel feeds from RF match, through a recursive transmission line current splitter network or a 4 legged “spider” 4 way transmission line splitter, with the far end of each coil segment grounded directly or through a capacitor. In all cases, the current through the segments can run in a clockwise (or anti-clockwise) manner, approximating the type of RF magnetic field one would get from a square loop coil. In an embodiment, the two ‘square’ coils can be driven independently at same or separated frequencies. If driven at the same frequency, they may be phase difference controlled, although this may be unnecessary. If driven at the same frequency, alternatively the two coils can be fed from a common match, with a variable impedance element (e.g., capacitor or inductor) to control current split between coils. In an embodiment, as the coils are shown, they are far enough apart (many skin depths at RF frequencies across range 400 kHz to 40+MHz and reasonable ICP driven plasma electron densities and practical low pressures for such a design) that constructive or destructive interference is negligible. In embodiments, additional ‘nested’ coils can be included. In embodiments, the coil segments do not have to form a square loop, but can rather be rectangular. In embodiments, the current ratio (or power ratio) can be used to control center-to-edge plasma or process uniformity across a range of gas mixtures, pressures, and powers. Embodiments can include a single, dual or multi-loop. Embodiments can include coil segments connected in series, with one single corner of each set driven, and next to it a ground point, through an optional capacitor.

In another aspect, a plasma chamber with rotating modulated cross-flow. Such rotating modulated cross-flow can be used in combination with the above described immersed inductively coupled and capacitively coupled plasma excitation methods, apparatuses and processes for large area substrates.

To provide context, traditional plasma chambers (i.e., CCP or ICP) typically inject gas axisymmetrically over a workpiece from gas inlet holes that are typically located directly above the workpiece or symmetrically around its periphery. Axisymmetric gas flow can result in pressure and concentration gradients and the gas hole inlets may breakdown, creating non-uniformities in the workpiece. That is, as wear occurs in gas holes in the dense, high |E| plasma regions, geometry of the holes change and as plasma penetrates, the holes may modify the local plasma characteristics in the vicinity of the holes. In addition, the local gas flow rate and velocity may change as a result of geometric changes. Therefore, the showerheads need to be replaced relatively often, increasing cost of the workpiece.

Accordingly, embodiments disclosed herein are directed to a plasma chamber (e.g., CCP or ICP) with a multiphase rotating modulated gas cross-flow for etching, deposition or other materials treatment. The plasma treatment chamber includes two or more gas injectors and two or more pump ports along a sidewall. In a first phase, one of the gas injectors forces a gas flow in one direction generally parallel and across a surface of a workpiece or device, where the gas is then pumped out via a pump port. In a second phase, gas flow is rotated by using another gas injector to force the gas flow in a different direction generally parallel and across the surface of the workpiece, where the gas is then pumped out via another pump port. In another embodiment, gas inlet valves coupled to the gas injector and/or throttle valves coupled to the pump ports can be used to modulate the rotating gas flows.

The plasma treatment chamber with rotating modulated gas cross-flow eliminates the need for showerheads (and gas inlet holes) in the dense, high |E| plasma regions, and therefore prevents the source of plasma non-uniformity. The disclosed embodiments prevent plasma from forming in gas holes due to proximity to dense plasma or breakdown due to high electric fields, leading to non-uniformity and plasma characteristics changing over time change. The disclosed embodiments avoid high center-to-edge pressure and concentration gradients that cause center-to-edge processing differences. Pressure distribution can be tailored across the plasma volume to minimize plasma non-uniformity. In addition, the disclosed embodiments eliminate stagnant low-gas velocity regions (i.e., center of the workpiece) for uniform reactant and byproduct removal.

FIGS. 11A-11C are diagrams illustrating embodiments of a plasma treatment chamber of a plasma reactor having a multiphase rotating crossflow operation. FIG. 11A is a diagram illustrating a top view of the plasma treatment chamber having a multiphase rotating crossflow operation according to one embodiment. FIGS. 11B and 11C illustrate cross-section views of the plasma treatment chamber in different embodiments.

Referring to both FIGS. 11A and 11B, the plasma treatment chamber 1100A includes one or more chamber sidewalls 1112 with a support surface 1114 therein to hold a workpiece 1116 (e.g., a semiconductor wafer; which can be a large substrate and/or a square substrate) for treatment. The plasma treatment chamber 1100 may be used to perform a variety of treatments to the workpiece 1116, such as etching, deposition, surface treatment or material modification, by distributing gases inside the chamber. For example, plasma treatment chamber 1100A may include, but is not limited to, a plasma etch chamber, a plasma enhanced chemical vapor deposition chamber, a physical vapor deposition chamber, an ion implantation chamber, an atomic layer deposition (ALD) chamber, an atomic layer etch (ALE) chamber, or other suitable vacuum processing chamber to fabricate various devices.

In one embodiment shown, the one or more sidewalls 1112 surround a processing region 1110 in which the workpiece 1116 (e.g., wafer or substrate) is treated. In the example shown, the plasma treatment chamber 1100A is shown with an axially symmetrical shape (e.g., a cylindrical) resulting in a single cylindrical sidewall 1112. However, in other embodiments, the plasma treatment chamber 100A may have any other shape, such as an oval, which also results in a single sidewall 1112, or as a square or rectangle, in which case the plasma treatment chamber 1100A would have four sidewalls.

According to the disclosed embodiments, the plasma treatment chamber 1100 includes at least two gas injectors 1118A and 1118B (collectively referred to as gas injectors 1118) and at least two pump ports 1120A and 1120B (collectively referred to as pump ports 1120) located generally along the sidewall(s) 1112. In one embodiment, the gas injectors are formed in the openings through a liner of the sidewall 1112. The plasma treatment chamber 1100A may be configured to use the gas injectors 1118 and the pump ports 1120 to rotate gas flows 1124 laterally across the workpiece 1116 to provide a multiphase rotating crossflow operation. In one embodiment, the multiphase rotating crossflow operation includes at least a 2-phase cycle, and may include a 3-phase cycle, a 4-phase cycle, and so on, wherein each phase gas is injected from one side of plasma treatment chamber 1100A and pumped out generally from an opposite side. As used herein, the phrase “located generally along the sidewall(s)” is intended to describe that any of the gas injectors 1118 and/or pump ports 1120 may be located in a sidewall or horizontally abutting or adjacent to the sidewall, or located in an outer periphery region of the chamber top or an outer periphery region of the chamber bottom.

Rotation of gas flow laterally across the workpiece 1116 may result in improved control of gas velocity and pressure gradients leading to better process uniformity across a wafer and from wafer-to-wafer.

Referring to FIG. 11B, the plasma treatment chamber 1100A further includes a chamber lid 1104 over the sidewall 1112. A support pedestal 1108 may include a support surface 1114 on which the workpiece 1116 is placed. In embodiments, the support pedestal 1108 and the support surface 1114 are fixed and not rotatable, and the workpiece 1116 affixed thereto is not rotated during processing. In an embodiment, the workpiece 1116 is electrostatically affixed to the support surface 1114. In another embodiment, the support surface 1114 is moveable in the axial direction for plasma gap adjustment or wafer transfer. A processing region 1110 in the plasma treatment chamber 1100A is defined by an area between the chamber lid 1104, the support pedestal 1108 (and support surface 1114), and the sidewall 1112. A chamber floor 1106 is beneath the sidewall 1112, and the chamber floor 1106 is below the processing region 1110. The support pedestal 1108 is below the chamber lid 1104 and above the chamber floor 1106, and is surrounded by the sidewall 1112. In embodiments, the chamber lid 1104 and the support surface 1114 may be separated by distance of approximately 50 mm-400 mm. In an embodiment, the plasma treatment chamber 1100A is a parallel plate capacitively coupled plasma (CCP) process chamber where a first electrode 1105 is above the workpiece 1116. A second electrode is included in a location 1113 in support pedestal 1108 below support surface 1114. In one embodiment, the first electrode 1105 is coupled to an RF source having a frequency in a range of 40-200 MHz with a power in a range of 200-10000 Watts. In one embodiment, the second electrode is coupled to ground. A plasma is generated above the wafer and between the two electrodes. In an embodiment, the workpiece 1116 is electrostatically clamped to the support surface 1114 by one or more clamping electrodes in or below the support surface 1114. In embodiments, the workpiece 1116 is coupled to biasing electrodes (e.g., at a low RF frequency in a range of 0.1 to 20 MHz) for additional plasma control during processing. The generated plasma may be pulsed during processing by pulsing the power to the first electrode 1105, which may be or include an ICP array, such as described in embodiments herein.

In an embodiment, the workpiece 1116 may include any substrate that is commonly used in semiconductor manufacturing environments. For example, the workpiece may include a semiconductor wafer. In an embodiment, semiconductor materials may include, but are not limited to, silicon or III-V semiconductor materials. The semiconductor wafer may be a semiconductor-on-insulator (SOI) substrate in some embodiments. Typically, semiconductor wafers have standard dimensions, (e.g., 200 mm, 300 mm, 450 mm, or even larger, and may be circular, square or rectangular). However it is to be appreciated that the workpiece 1116 may have any dimension. Embodiments may also include workpieces that include non-semiconductor materials, such as glass or ceramic materials. In an embodiment, the workpiece 1116 may include circuitry or other structures manufactured using semiconductor processing equipment. In yet another embodiment, the workpiece 1116 may include a reticle or other lithography mask object.

FIGS. 11A and 11B illustrate an example of 2-phase cycle rotating cross-flow operation. In the first phase, gas injector 1118A injects a first gas flow 1124A in a first direction generally parallel to and across a surface of the workpiece 1116 and has an opposing pump port 1120A along the one or more sidewalls 1112 generally opposite of the gas injector 1118A to pump out the gas flow 1124A. In the second phase, gas injector 1118B injects a second gas flow 1124B in a second direction generally parallel to and across a surface of the workpiece 1116 and has an opposing pump port 1120B along the one or more sidewalls 1112 generally opposite of the gas injector 1118B to pump out the gas flow 1124B. In embodiments, the direction of the second gas flow 1124B is different from the direction of the first gas flow 1124A. In one embodiment, generally parallel means within approximately 0° to 15°, and generally opposite means within approximately 0° to 30°.

Thus, gas injector 1118A and the opposing pump port 1120A form one gas injector-pump port pair, while gas injector 1118B and opposing pump port 1120B form a second gas injector-pump port pair. In one embodiment, each of the gas injectors 1118A and 1118B may include an array of individual gas injectors, as shown in FIG. 11A. In an alternative embodiment, each of the gas injectors 1118A and 1118B includes only a single vent gas injector. In some embodiments, gas injector 1118A includes an array of individual gas injectors, and gas injector 1118B is a single vent gas injector, or vice versa.

As shown in FIG. 11A, along the horizontal plane, which is generally parallel to the orientation of the workpiece 1116, each gas injector-pump port pair (i.e., a gas injector and the opposing pump port) are symmetrically located along the sidewall 1112 of the plasma treatment chamber 1100A. Any number of gas injectors 1118 and pump ports 1120 may be provided. In general one gas injector-pump port pair may be offset from an adjacent injector-pump port pair locations by an angle equal to 360 total degrees divided by the number of injector-pump port pairs to ensure equal distribution of the gases. For example, with two injector-pump port pairs, the injector-pump port pairs are offset from one another by 180° (360°/2). With three injector-pump port pairs, the injector-pump port pairs are offset by 120°, and so on. In some embodiments, as shown, a gas injector span is smaller than a span of the corresponding pump port. In other embodiments, the gas injector span is the same as the span of the corresponding pump port. In other embodiments, the gas injector span is larger than the span of the corresponding pump port. Gas can be injected from gas injector openings of various geometry such as holes, slots, and the like, and different gas injectors can have the same or different geometries and sizes.

While in some embodiments, the number of gas injectors 1118 and pump ports 1120 is equal, in other embodiments, the number of gas injectors 1118 and pump ports 1120 may differ. In some embodiments, a single pump port is associated with a corresponding gas injector, as depicted. In other embodiments, an array of pump ports is associated with a corresponding gas injector.

As shown in FIG. 11B, the gas injectors 1118 are located in openings in the sidewall 1112 in the processing region 1110. For example, the openings may be located within a liner of the sidewall 1112. In an embodiment, the openings in the sidewall 1112 are in a location vertically between the chamber lid 1104 and the substrate support pedestal 1108. In the embodiment shown, the openings in the sidewall 1112 are adjacent to a bottom of the chamber lid 1104.

Along the vertical plane, which is generally parallel to the orientation of the support pedestal 1108, locations of the pump ports 1120 may be vertically offset from locations of the gas injectors 1118 by a distance approximately equal to the distance between a bottom of the chamber lid 1104 and a top of the support pedestal 1108 in one embodiment. In this embodiment, the pump ports 1120 may be located in cavities between the sidewall 1112 and the support pedestal 1108, and above the chamber floor 1106. In another embodiment, the pump ports 1120 may be located in additional openings in the sidewall 1112 anywhere between the chamber lid 1104 and the chamber floor 1106. In another embodiment, gas can be injected from peripheral regions of the chamber top, and/or pumped from peripheral regions of the chamber bottom, and over the workpiece processing region and still flow substantially parallel to the workpiece.

As described above, the plasma treatment chamber 1100A of the disclosed embodiments injects gas generally parallel and across the workpiece 1116. This is in contrast to a typical axisymmetric top-down gas flow injection from a “showerhead” electrode in a CCP source reactor, and in contrast to a radial outward/downward gas injection from a nozzle array near a central axis in an ICP or microwave source reactor. In addition, instead of a pump port or pumping plenum located axisymmetrically around the periphery of the workpiece, in embodiments, gas is preferentially pumped out from a side of a workpiece generally opposite the injection side.

In embodiments, the gas flow 1124 of each cross flow phase can be switched on and off to control gas flow rotation. In another embodiment, instead of switching the gas flow 1124 on and off, a modulating function may be applied to a flow rate of the gas flows 1124 from the gas injectors 1118 and/or to an outlet conductance (or pressure) caused by the pump ports 1120 to either approximate open/closed states or to ramp between states using a modulating function, such as sinusoidal. As shown in FIG. 11B, a flow rate of one or both of the first and second gas flows 1124A and 1124B can be modulated using one or more gas inlet valves 1122A and 1122B (e.g., piezoelectric valves) that are coupled to gas injector 1118A and 1118B, respectively. In embodiments, the gas inlet valves 1122A and 1122B are coupled to one or more gas sources 1126, such that a single type of gas, or a mixture of different types of gases, may be injected into the processing region 1110 during each rotation phase. In one embodiment, a constant total gas flow may be applied by the gas injectors 1118 to smoothly and sequentially inject the gas flows across the different sides of the workpiece 1116 in a complete cycle, which may then be repeated as necessary.

In addition, in some embodiments one or more of the pump ports 1120 may be modulated. For example, pump port conductance (pressure) may be modulated using individual pressure control valves 1127A and 1127B on pump ports 1120A and 1120B. Also shown is that the pump ports 1120A and 1120B are coupled to one or more pumps 1132 to evacuate the gas. In the example shown, pressure control valve 1127A in pump port 1120A is in the closed position, while pressure control valve 1127B is shown in the open position to expel the first gas flow 1124A. The pressure control valves 1127A and 1127B may be operated smoothly between two states of conductance or pressure, which are then cycled through in a like sequence as the gas injectors 1118A and 1118B. In one embodiment, pressure control valves 1127A and 1127B include throttle valves.

The plasma chamber 1100A may inject a variety of types of process gases. Exemplary process gases may include the following: i) dielectric etch gases including one or more of CF4, C2F6, CHF3, C4F8, C4F6, C3F6, CH2F2, C3H2F4, NF3, SF6; ii) deposition gases including one or more of CH4, C2H2, CH3F; iii) additional gases for co-flow for either etch or deposition including one or more of Ar, N2, O2, He, Kr, Xe, COS; iv) semiconductor material etch deposition gases including one or more of SiCl4, SiCH2Cl2; v) hydride-based deposition gases including one or more of BH3, AlH3, GaH3, NH3; vi) oxide material etch deposition gases including one or more of SiCl4, SiCH2Cl2, and O2; and vii) annealing gases including one or more of NH3, N2, Ar.

In some embodiments, the plasma treatment chamber 1100A may further include sensors 1131 and systems to monitor process chamber conditions including gas flow, velocity, pressure, temperature and the like, with high sensitivities and real time measurement. Particular embodiments can include capacitive wall sensors, on-chip or off-chip thermal sensors, pressure sensors, and/or integrated sensors (capacitive sensors and thermal sensors) on substrates such as ceramic substrate or glass or silicon or flexible substrates. In some embodiments, the sensors can be distributed throughout the chamber to monitor the chamber conditions at various locations, which then can be correlated to overall process performances such as etch rate, etch non-uniformity, particle generation, process drifting, pressure uniformity, etc., In one embodiment, a plurality or an array of pressure sensors can be distributed throughout the chamber to provide data regarding gas flow (e.g., rotation rates, uniformity, velocity) during processing.

FIG. 11B further shows that the plasma treatment chamber 1100A may be connected to a controller 1140, which in turn may be connected to a user interface 1142. In some embodiments, the controller may be coupled to the gas inlet valves 1122, the pressure control valves 1127, the gas sources 1126, the pump 1132 and the sensors 1131 to control operation of the plasma treatment chamber 1100A. A user may set process parameters and monitor operation of the plasma treatment chamber 1100A through the controller 1140 from the user interface 1142.

The multiphase architecture of the plasma treatment chamber enables many different configuration options. For example, FIG. 11C illustrates a cross-section view of the plasma treatment chamber 1100B in an embodiment that includes a top-down gas flow in addition the one or more pairs of gas injectors 1118 and pump ports 1120 that provide side-to-side gas flows. In this embodiment, chamber lid 1104 may be configured with a showerhead plate 1128 (the controller and UI of FIG. 11B are not shown for simplicity). The shower head plate 1128 may have a central manifold 1129 and one or more outer manifolds 1130 for distributing gases into the processing region 1110 along with gases distributed by the gas injectors 1118A and 1118B. Using the showerhead plate 1128, additional gases may be introduced into the chamber with a vertical velocity component, but injection of gasses from one side by gas injector 1118A and pumping out on other side of workpiece 1116 by pump port 1120B generally results in a horizontal component of gas velocity across much of the workpiece 1116. Likewise, while the pump ports 1120 may be on the sidewall 1112, or on an upper or lower surface of chamber, the pump ports 1120 are generally across from the injection side. Therefore, while there may be a component of velocity of exiting gas in the vertical direction, gas velocity is generally horizontal and parallel to the workpiece 1116 in the region above workpiece 1116.

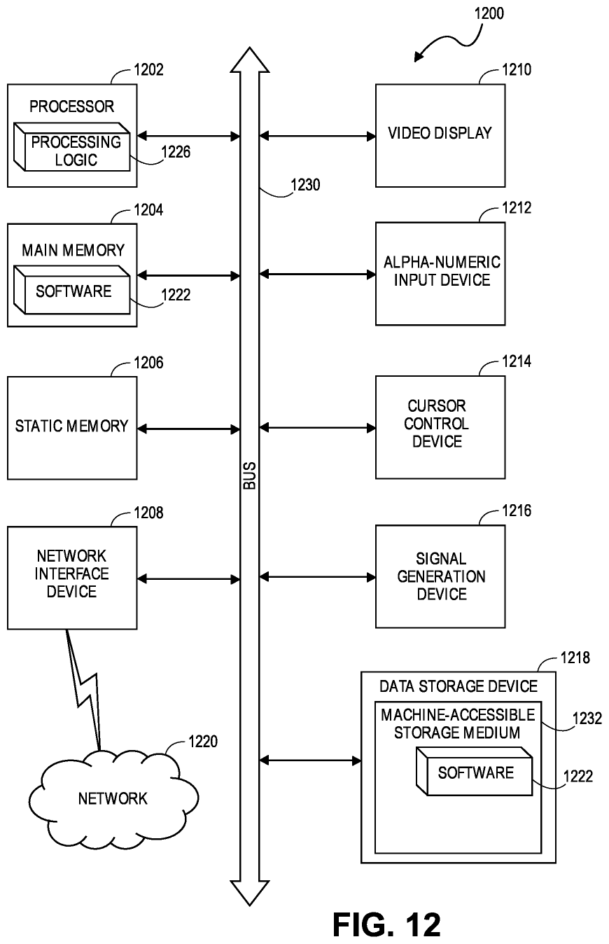

FIG. 12 illustrates a diagrammatic representation of a machine in the exemplary form of a computer system 1200 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 1200 includes a processor 1202, a main memory 1204 (e.g., read-only memory (ROM), flash memory, dynamic random access memory (DRAM) such as synchronous DRAM (SDRAM) or Rambus DRAM (RDRAM), etc.), a static memory 1206 (e.g., flash memory, static random access memory (SRAM), MRAM, etc.), and a secondary memory 1218 (e.g., a data storage device), which communicate with each other via a bus 1230.

Processor 1202 represents one or more general-purpose processing devices such as a microprocessor, central processing unit, or the like. More particularly, the processor 1202 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 1202 may also be one or more special-purpose processing devices such as an application specific integrated circuit (ASIC), a field programmable gate array (FPGA), a digital signal processor (DSP), network processor, or the like. Processor 1202 is configured to execute the processing logic 1226 for performing the operations described herein.

The computer system 1200 may further include a network interface device 1208. The computer system 1200 also may include a video display unit 1210 (e.g., a liquid crystal display (LCD), a light emitting diode display (LED), or a cathode ray tube (CRT)), an alphanumeric input device 1212 (e.g., a keyboard), a cursor control device 1214 (e.g., a mouse), and a signal generation device 1216 (e.g., a speaker).

The secondary memory 1218 may include a machine-accessible storage medium (or more specifically a computer-readable storage medium) 1232 on which is stored one or more sets of instructions (e.g., software 1222) embodying any one or more of the methodologies or functions described herein. The software 1222 may also reside, completely or at least partially, within the main memory 1204 and/or within the processor 1202 during execution thereof by the computer system 1200, the main memory 1204 and the processor 1202 also constituting machine-readable storage media. The software 1222 may further be transmitted or received over a network 1220 via the network interface device 1208.

While the machine-accessible storage medium 1232 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

Embodiments of immersed inductively coupled and capacitively coupled plasma excitation methods, apparatuses and processes for large area substrates have been disclosed.

What is claimed is:

1. A plasma process chamber, comprising:
a pedestal for supporting a workpiece in a processing volume;
an array of inductive elements in a portion of the processing volume above the pedestal, the array of inductive elements comprising a plurality of parallel and planar inductive elements; and
a chamber top or lid over the array of inductive elements.

2. The plasma process chamber of claim 1, wherein RF bias is applied to the pedestal with respect to a chamber ground.

3. The plasma process chamber of claim 1, wherein each one of the plurality of parallel and planar inductive elements comprises a conductive rod or tube surrounded by a dielectric tube.

4. The plasma process chamber of claim 3, wherein each one of the plurality of parallel and planar inductive elements further comprises a Faraday shield or electrostatic shield between the conductive rod or tube and the dielectric tube.

5. The plasma process chamber of claim 3, wherein the dielectric tube is cooled from the inside.

6. The plasma process chamber of claim 1, wherein the array of inductive elements penetrates through mutually opposite walls of the process chamber.

7. The plasma process chamber of claim 1, wherein the array of inductive elements is fed RF current from a matching network via a recursive transmission line current-splitting structure from one side of the array of inductive elements.

8. The plasma process chamber of claim 7, wherein a second, opposite side of the array of inductive elements has current returned to the matching network or to ground through a recursive transmission line current-combining structure.

9. The plasma process chamber of claim 1, further comprising one or more capacitors coupled in parallel with the array of inductive elements.

10. The plasma process chamber of claim 1, further comprising one or more capacitors coupled in series with the array of inductive elements.

11. The plasma process chamber of claim 1, wherein the array of inductive elements is configured for aiding RF magnetic fields.

12. The plasma process chamber of claim 1, wherein the array of inductive elements is configured for opposing RF magnetic fields.

13. The plasma process chamber of claim 1, wherein the array of inductive elements is configured electrically driven in parallel.

14. The plasma process chamber of claim 1, wherein the array of inductive elements is configured electrically driven in series.

15. The plasma process chamber of claim 1, wherein the pedestal includes an electrostatic chuck.

16. A plasma process chamber, comprising:
a pedestal for supporting a workpiece in a processing volume;
an array of inductive elements in a portion of the processing volume above the pedestal, the array of inductive elements having a rectangular loop arrangement; and
a chamber top or lid over the array of inductive elements.

17. The plasma process chamber of claim 16, wherein RF bias is applied to the pedestal with respect to a chamber ground.

18. The plasma process chamber of claim 16, wherein each one of the array of inductive elements comprises a conductive rod or tube surrounded by a dielectric tube.

19. The plasma process chamber of claim 18, wherein each one of the plurality of inductive elements further comprises a Faraday shield or electrostatic shield between the conductive rod or tube and the dielectric tube.

20. The plasma process chamber of claim 18, wherein the dielectric tube is cooled from the inside.

21. The plasma process chamber of claim 16, wherein the rectangular loop arrangement is a single loop arrangement, a dual loop arrangement, or a multi-loop arrangement.

22. The plasma process chamber of claim 16, wherein the rectangular loop arrangement comprises coil segments electrically connected in series or parallel.

23. The plasma process chamber of claim 16, wherein the pedestal includes an electrostatic chuck.

24. An apparatus for including in a plasma process chamber, the apparatus comprising:
an array of inductive elements comprising a plurality of parallel and planar inductive elements, each one of the plurality of parallel and planar inductive elements comprising a conductive rod or tube surrounded by a dielectric tube.

25. The apparatus of claim 24, wherein the array of inductive elements is configured to be fed RF current from a matching network via a recursive transmission line current-splitting structure from one side of the array of inductive elements, and wherein a second, opposite side of the array of inductive elements is configured to have current returned to the matching network or to ground through a recursive transmission line current-combining structure.
